(19) United States
(12) Patent Application Publication
(10) Pub. No.: US 2005/0285257 A1
(43) Pub. Date: Dec. 29, 2005

(54) Encapsulated device with heat isolating structure

(76) Inventors: Jeffrey Chen, Tao Yuan Hsien (TW); Chung-Zen Lin, Tao Yuan Hsien (TW); Wen-Fu Hsu, Tao Yuan Hsien (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/983,621

(22) Filed: Nov. 9, 2004

(30) Foreign Application Priority Data
Jun. 23, 2004 (TW) 93118036

(51) Int. Cl. H01L 23/10

(52) U.S. Cl. 257/706

(57) ABSTRACT

The present invention provides an encapsulated device with heat isolating structure and a reflow soldering method thereof. The encapsulated device has a micro heat spreader with vapor chamber formed on the surface, and a cover covers the encapsulated device and wraps the micro heat spreader. A hermetical space is formed to isolate the high temperature when forming the solder balls and performing the SMT process, and prevent the micro heat spreader from being damaged. The present invention can provide an encapsulated device with heat isolating structure and a reflow soldering method thereof to protect the product in the reflow soldering process and improve the yield, and the cover can be reused to lower the cost.

### BACKGROUND OF INVENTION

1. Field of the Invention

The invention relates to an encapsulated device with heat isolating structure, and more particularly, to a heat isolating structure used in the reflow soldering process when manufacturing the encapsulated device and the surface mount technology.

2. Description of the Prior Art

As the trend of high performance, high speed and miniaturization, heat dissipation issue has become a key technology of the electric devices. Especially, as development of the nanometer class CPU, the heat points concentrating in a small capacity make this issue more troublesome. Hence, the research and application of heat management material and technology is become an important subject of the high tech industries.

In surface mount technology (SMT), the powder material is applied widely in the heat management field, wherein the micro heat spreader with vapor chamber is going to be used as the heat dissipation material in the semiconductor devices. When adhering the encapsulated devices, the solder balls are firstly formed on the metal pads of the encapsulated devices, and the contact points for the solder damply adhering are formed on the substrate corresponding to the solder balls on the chips. Then, the encapsulated device is aimed at the contact points on the substrate to connect simultaneously with the reflow soldering process. However, the reflow soldering process is performed at the temperature higher than 220° C., and the micro heat spreader on the encapsulated device will become deformed or cracked. That situation will damage the products and lower the yield.

Hence, the present invention provides an encapsulated device with heat isolating structure to prevent the heat damaging the micro heat spreader of the encapsulated device when forming the solder ball and performing the SMT process.

### SUMMARY OF INVENTION

It is therefore a primary objective of the claimed invention to provide an encapsulated device with heat isolating structure that can prevent the heat directly contacting the micro heat spreader in the reflow soldering process and avoid the high temperature damaging the micro heat spreader.

It is therefore another objective of the claimed invention to provide an encapsulated device with heat isolating structure that utilizes the lodging structure on the cover to fix the encapsulated device. It is convenient to assemble and disassemble, and the cover can be also reused to lower the cost.

It is therefore a further objective of the claimed invention to provide a cover to protect the micro heat spreader, prevent the micro heat spreader from being damaged or lowering the heat dissipation function, and improve the reliability of the encapsulated device.

According to the claimed invention, an encapsulated device with heat isolating structure includes an encapsulated device formed a layer of micro heat spreader and covered with a cover. The cover can lodge the encapsulated device and expose the ball grid array on lower surface of the encapsulated device. The reflow process in the stove will solder the ball grid array to connect the encapsulated device on the printed circuit board.

These and other objectives of the present invention will no doubt become obvious to those of ordinary skill in the art after reading the following detailed description of the preferred embodiment that is illustrated in the various figures and drawings.

### BRIEF DESCRIPTION OF DRAWINGS

FIG. 1 is a cross section of the present invention.

FIGS. 2(a) to 2(c) are cross sections of fabricating steps of an reflow soldering method of encapsulated device with heat isolating structure according to the present invention.

| | |
|---|---|
| 202 | cover |
| 204 | mortise |
| 206 | flip-chip solder ball |
| 30 | flip-chip encapsulated device |
| 301 | micro heat spreader |
| 302 | chip |
| 304 | chip solder ball |
| 308 | substrate |
| 400 | printed circuit board |

### DETAILED DESCRIPTION

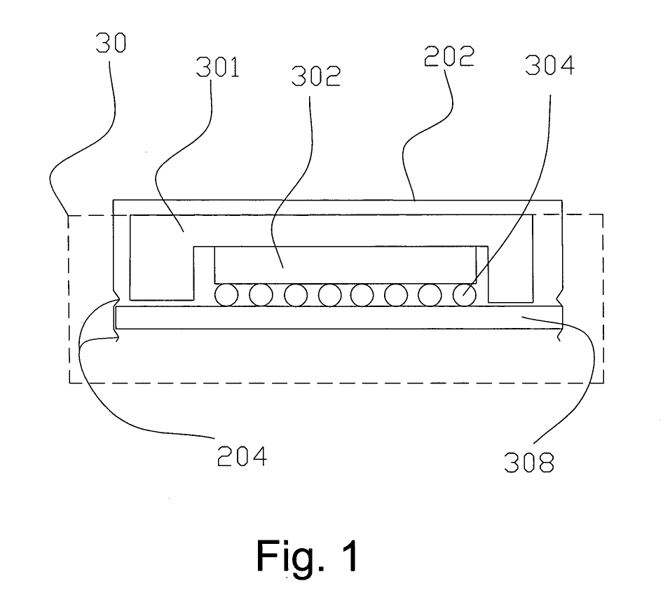

The present invention discloses an encapsulated device with heat isolating structure. FIG. 1 shows a cross section of the present invention. The encapsulated device with heat isolating structure includes a flip-chip encapsulated device 30, which has a chip 302 formed on a substrate 308. The lower surface of the chip 302 is formed several chip solder balls 304 to electrically connect the substrate 308, and a glue (not shown) is filled between the chip solder balls 304 to protect the chip solder balls 304 and fix the chip 302 onto the substrate 308. In addition, a micro heat spreader 301 is located on surface of the flip-chip encapsulated device 30, and the micro heat spreader 301 has a vapor chamber that can dissipate the hot spots of the chip 302 while operating. A layer of heat conductive glue is formed between the micro heat spreader 301 and the chip 302 to fix the micro heat spreader 301 onto the chip 302. Furthermore, a cover 202 covers the flip-chip encapsulated device 30 and wraps the micro heat spreader 301. Lower edge of the cover 202 has several mortises 204 fixing with periphery of the substrate 308, and material of the cover 202 is light metal, heat-resistant macromolecule or compound material that can effectively isolate the heat source, wherein the light metal can be alloy of aluminum, magnesium or titanium.

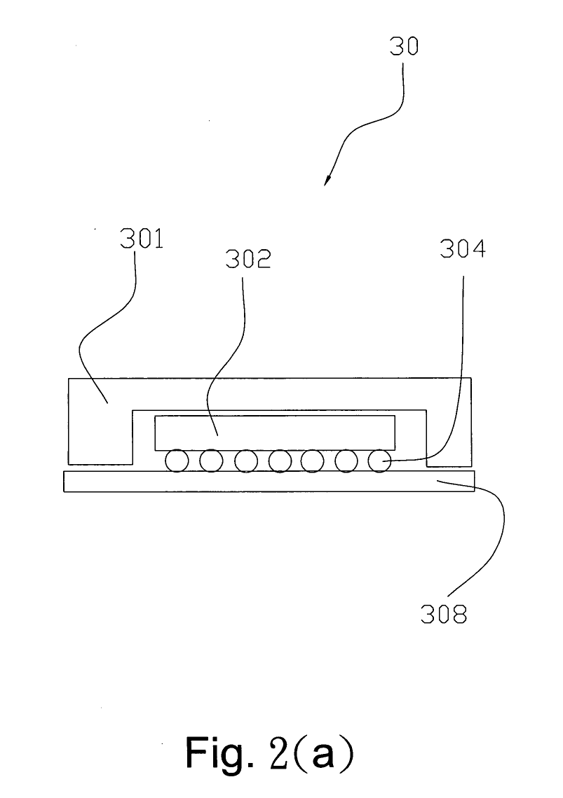

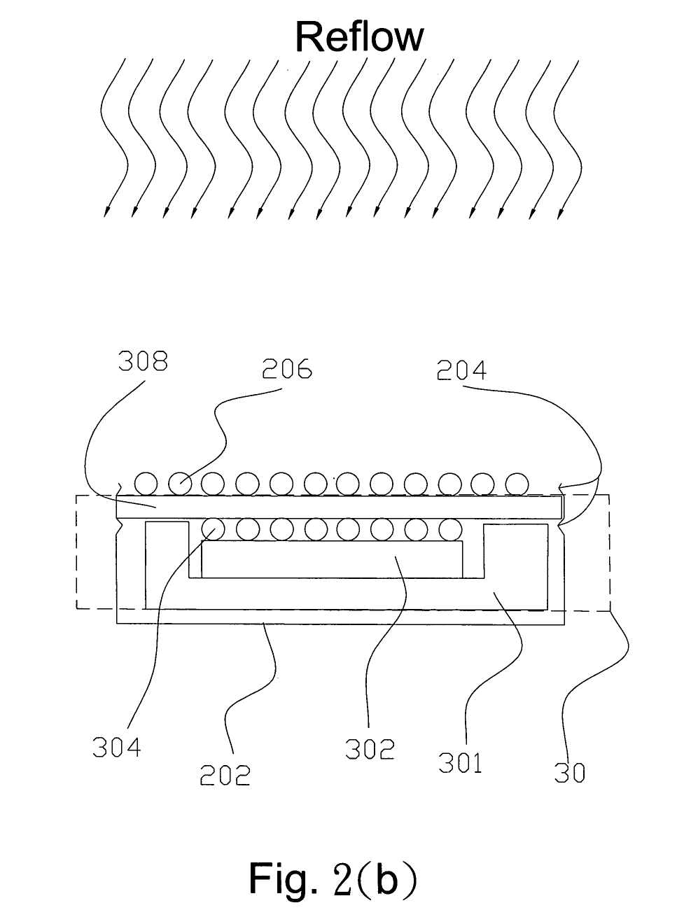

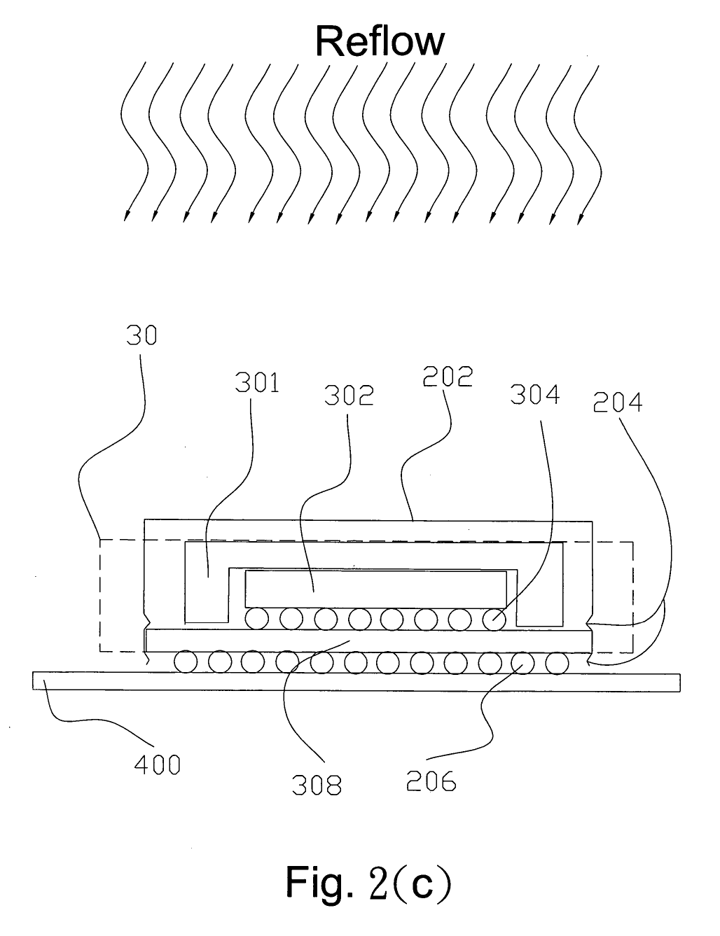

FIGS. 2(a) to 2(c) are cross sections of fabricating steps according to the present invention. Firstly, as shown in FIG. 2(a), an encapsulated device 30 is provided, whose upper surface has a micro heat spreader 301 and lower surface has a substrate 308. Then, as shown in FIG. 2(b), a cover 202 is located on surface of the flip-chip encapsulated device 30, and the mortises 204 formed on lower edge of the cover 202 are fixed with periphery of the substrate 308. The micro heat spreader 301 is wrapped in a hermetical space, and lower surface of the substrate 308 is exposed. The flip-chip encapsulated device 30 is reversed and putted into a reflow stove (not shown) to reflow solder the flip-chip solder balls 206 onto the contact points on lower surface of the substrate 308 correspondingly. The flip-chip solder balls 206 are arranged in the ball grid array method, and the high temperature over 220° C. produced in the reflow soldering process is isolated by the cover 202 to prevent conducting to the micro heat spreader 301. Then, as shown in FIG. 2(c) the flip-chip encapsulated device 30 is reversed again and placed on a printed circuit board 400 to perform the reflow soldering process with surface mount technology (SMT). The flip-chip solder balls 206 are reflow soldered in the reflow stove, and the flip-chip solder balls 206 are fused in high temperature over 220° C. and electrically connected to surface of the printed circuit board 400. The cover 202 protects the surface mount device and prevents the micro heat spreader 301 from being damaged by the high temperature.

Lower edge of the cover 202 can be designed not only the mortise 204 but also a tenon (not shown), which can lodge with the flip-chip encapsulated device 30. Shape of the cover 202 is designed according to shape of the micro heat spreader 301. The cover 202 can be further sold with the flip-chip encapsulated device 30 as a packaged product, or taking off the cover 202 and reusing in the reflow soldering process to lower the cost. If the cover 202 is only used in the reflow soldering process without being sold with the flip-chip encapsulated device 30, the cover can be designed with no lodging structure and the cross section of the cover is C-shaped. The cover 202 isn't limited using only in the embodiment of the flip-chip encapsulated device 30, it can be applied to all encapsulated devices using the micro heat spreader 301. The heat isolation of the micro heat spreader 301 in the reflow soldering process is included in the present invention.

In contrast to the prior art, the present invention utilizes the cover to wrap the micro heat spreader on the flip-chip encapsulated device to form a hermetical space, so that the high temperature over 220° C. produced in the reflow soldering process can be isolated and preventing damaging the micro heat spreader. Hence, the present invention not only solves the problem of the micro heat spreader easily damaged in the reflow soldering process but also provides a heat isolating structure to ensure the heat dissipation reliability of the micro heat spreader and improve the product yield of the encapsulated device.

Those skilled in the art will readily observe that numerous modifications and alterations of the device may be made while retaining the teachings of the invention. Accordingly, the above disclosure should be construed as limited only by the metes and bounds of the appended

1. An encapsulated device with heat isolating structure, comprising:
an encapsulated device;
a micro heat spreader located on said encapsulated device; and
a cover located on said micro heat spreader, lower edge of said cover has several lodging structures fixing with periphery of said encapsulated device to make said cover isolating heat and protecting said micro heat spreader.

2. The encapsulated device with heat isolating structure of claim 1, wherein said encapsulated device further comprises:
a substrate, whose lower surface is formed a ball grid array; and
a chip located on said substrate.

3. The encapsulated device with heat isolating structure of claim 2, wherein said chip is electrically connected to said substrate via a plurality of solder balls.

4. The encapsulated device with heat isolating structure of claim 2, wherein a glue is filled between said chip and said substrate.

5. The encapsulated device with heat isolating structure of claim 1, wherein a heat conductive glue is formed between said micro heat spreader and said encapsulated device.

6. The encapsulated device with heat isolating structure of claim 1, wherein said micro heat spreader has a vapor chamber.

7. The encapsulated device with heat isolating structure of claim 1, wherein material of said cover is selected from one of light metal, heat-resistant macromolecule and compound material.

8. The encapsulated device with heat isolating structure of claim 1, wherein said lodging structure is selected from one of mortise and tenon.

9. The encapsulated device with heat isolating structure of claim 1, wherein cross section of said cover is C-shaped.

10. The encapsulated device with heat isolating structure of claim 1, wherein shape of said cover corresponds to shape of said micro heat spreader.

11. The encapsulated device with heat isolating structure of claim 1, wherein solder balls are formed on lower surface of said substrate with ball grid array method, then put into stove reversely and reflow soldered in high temperature.

12. The encapsulated device with heat isolating structure of claim 1, wherein said encapsulated device is reflow soldered to make said solder balls fusing in high temperature and electrically connecting the printed circuit board with surface mount technology (SMT).
